(19) United States
(12) Patent Application Publication
(10) Pub. No.: US 2005/0230351 A1
(43) Pub. Date: Oct. 20, 2005

(54) Plasma processing method and apparatus

(75) Inventor: Shigeru Tahara, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/067,706

(22) Filed: Mar. 1, 2005

(30) Foreign Application Priority Data
Mar. 2, 2004 (JP) 2004-057290

(51) Int. Cl. C23F 1/00; H01L 21/302

(52) U.S. Cl. 216/67; 438/710; 156/345.43

(57) ABSTRACT

There are provided a plasma processing method and plasma processing apparatus capable of, when ashing a substrate to be ashed having an organic low-k film and a resist film formed thereon to thereby remove the resist film, reducing damages inflicted on the organic low-k film compared with the prior art.

A pressure in a plasma processing chamber 102 is set to 4 Pa or below, a first high frequency electric power supply 140 applies an electric power of 0.81 W/cm² or below as a high frequency electric power of a first frequency to an upper electrode 121 to generate an O₂ plasma, and a second high frequency electric power supply 150 applies a second high frequency electric power having a second frequency lower than the first frequency to a susceptor (the lower electrode) 105 to generate a self-boas voltage.

### FIELD OF THE INVENTION

The present invention relates to a plasma processing method and a plasma processing apparatus for ashing a target substrate having an organic low-k film and a resist film formed thereon to remove the resist film.

### BACKGROUND OF THE INVENTION

In a fabrication process of a semiconductor apparatus, a photolithography technique employing a resist film is used for, e.g., forming a wiring pattern. In case of such a photolithography technique employing a resist film, after an etching treatment or the like is carried out by using a resist film as a mask to form a pattern as intended, the resist film having served as a mask needs to be removed. Among methods for removing a resist film, there is known a method of ashing the resist film with oxygen plasma (for example, see Reference 1). Further, in case of ashing the resist film by using an oxygen plasma, there is known a method employing an additional gas, e.g., an Ar or He gas (for example, see Reference 2).

In case of using, for example, an organic low-k film such as a low-k film made of organic polysiloxane, after ashing a resist film with oxygen plasma, the oxygen plasma may inflict damage on the organic low-k film, thereby causing an increase in a dielectric constant thereof. Accordingly, there has been provided a method for reducing damage to be inflicted on the organic low-k film by lowering a pressure in a plasma chamber down to within a range between 4.00 and 20.0 Pa and then performing the ashing with oxygen plasma (for example, see Reference 3).

(Reference 1) Japanese Patent Laid-open Application No. 2003-17469 (Pages 3-5, FIGS. 1-4)

(Reference 2) Japanese Patent Laid-open Application No. H6-45292 (Pages 2-3, FIG. 1)

(Reference 3) U.S. Pat. No. 6,670,276 (Cols. 1-8, FIG. 1-5(d))

Conventionally, as described above, the ashing with oxygen plasma is carried out by lowering a pressure in a plasma chamber down to within a range between 4.00 and 20.0 Pa to reduce damage to be inflicted on an organic low-k film.

However, there are demands for further reducing damage to be inflicted on an organic low-k film during an ashing process as well as restraining the increase in a dielectric constant thereof.

### SUMMARY OF THE INVENTION

The present invention is presented to solve the above-mentioned problems by providing a plasma processing apparatus and a plasma processing method capable of further reducing damage inflicted on an organic low-k film compared to conventional methods while ashing a target substrate having an organic low-k film and a resist film formed thereon with plasma to remove the resist film.

A plasma processing method of claim 1, using a processing gas including at least oxygen to ash a substrate to be ashed having an organic low-k film and a resist film formed thereon to thereby remove the resist film, wherein a pressure in a plasma processing chamber is 4 Pa or less, includes the step of applying a first high frequency electric power having a first frequency to generate plasma of the processing gas; and the step of applying a second high frequency electric power having a second frequency lower than the first frequency to an electrode having the substrate to be ashed mounted thereon to thereby generate a self-bias voltage, wherein an applied voltage of the first high frequency electric power is 0.81 W/cm² or less.

A plasma processing method of claim 2 is the plasma processing method of claim 1, wherein the organic low-k film includes Si, O, C and H.

A plasma processing method of claim 3 is the plasma processing method of claim 1, wherein an upper electrode is placed in the plasma processing chamber to confront the electrode having the substrate to be ashed mounted thereon and the first high frequency electric power is applied to the upper electrode.

A plasma processing method of claim 4 is the plasma processing method of claim 1, wherein the pressure in the plasma processing chamber is 1.3 Pa or higher.

A plasma processing method of claim 5 is the plasma processing method of claim 1, wherein an applied voltage of the second high frequency electric power ranges inclusively between 0.28 W/cm² and 0.66 W/cm².

A plasma processing method of claim 6 is the plasma processing method of claim 1, wherein the processing gas is an O₂ gas.

A plasma processing method of claim 7 is the plasma processing method of claim 1, wherein the processing gas is a gaseous mixture of O₂/Ar, and a ratio of an O₂ flow rate with respect to an O₂/Ar flow rate is 40% or higher.

A plasma processing method of claim 8 is the plasma processing method of claim 1, wherein the processing gas is a gaseous mixture of O₂/He, and a ratio of an O₂ flow rate with respect to an O₂/He flow rate is 25% or higher.

A plasma processing apparatus of claim 9 for ashing a substrate to be ashed having an organic low-k film and a resist film mounted thereon to remove the resist film includes a plasma processing chamber in which a pressure is 4 Pa or lower; a processing gas supply unit for supplying a processing gas including at least oxygen into the plasma processing chamber; an electrode placed in the plasma processing chamber and having the substrate to be ashed mounted thereon; a first high frequency electric power supply unit for applying a high frequency electric power having a first frequency and a magnitude of 0.81 W/cm² or less; and a second high frequency electric power supply unit for applying a high frequency electric power having a second frequency to generate a self-bias voltage.

A plasma processing apparatus of claim 10 is the plasma processing apparatus of claim 9, wherein an upper electrode is placed in the plasma processing chamber to confront the electrode having the substrate to be ashed mounted thereon and the first high frequency electric power supply unit supplies the high frequency electric power.

A plasma processing apparatus of claim 11 is the plasma processing apparatus of claim 9, wherein the pressure in the plasma processing chamber is 1.3 Pa or higher.

A plasma processing apparatus of claim 12 is the plasma processing apparatus of claim 9, wherein the second high frequency electric power supply unit supplies an electric power ranging between 0.28 W/cm² and 0.66 W/cm².

A plasma processing apparatus of claim 13 is the plasma processing apparatus of claim 9, wherein the processing gas supply unit supplies an O₂ gas.

A plasma processing apparatus of claim 14 is the plasma processing method of claim 9, wherein the processing gas supply unit supplies a gaseous mixture of O₂/Ar, and a ratio of an O₂ flow rate with respect to an O₂/Ar flow rate is 40% or higher.

A plasma processing apparatus of claim 15 is the plasma processing method of claim 9, wherein the processing gas supply unit supplies a gaseous mixture of O₂/He, and a ratio of an O₂ flow rate with respect to an O₂/He flow rate is 25% or higher.

In accordance with a plasma processing method and a plasma processing apparatus of the present invention, damage inflicted on an organic low-k film can be further reduced compared to conventional methods while ashing a target substrate having an organic low-k film and a resist film mounted thereon with plasma to remove the resist film.

### BRIEF DESCRIPTION OF THE DRAWINGS

The above and other objects and features of the present invention will become apparent from the following description of preferred embodiments, given in conjunction with the accompanying drawings, in which:

FIG. 1 shows a schematic configuration of a plasma processing apparatus in accordance with a preferred embodiment of the present invention;

FIGS. 2A to 2D illustrate a method for evaluating a plasma processing method in accordance with a preferred embodiment of the present invention;

FIG. 3 provides a table depicting ashing conditions and evaluation results thereof;

FIG. 4 presents a graph illustrating a result of a multiple regression analysis;

FIG. 5 offers a graph showing a relation between decrement in an organic low-k film and pressure;

FIG. 6 provides a graph depicting a relation between decrement in the organic low-k film and electric power applied to an upper electrode;

FIG. 7 presents a graph representing a relation between decrement in the organic low-k film and electric power applied to the lower electrode;

FIG. 8 offers a graph illustrating a relation between decrement in the organic low-k film and total flow rate of a processing gas;

FIG. 9 provides a graph showing a relation between decrement in the organic low-k film and O₂ ratio;

FIG. 10 presents a graph depicting predicted values and actually measured values of top CD decrement;

FIG. 11 offers a graph representing a correlation between decrement in a thermal oxide film (Ox) and increase in facet;

FIG. 12 provides a graph illustrating a result of a multiple regression analysis;

FIG. 13 presents a graph showing a relation between decrement in the thermal oxide film (Ox) and pressure;

FIG. 14 offers a graph depicting a relation between decrement in the thermal oxide film (Ox) and the electric power applied to the upper electrode;

FIG. 15 provides a graph representing a relation between decrement in the thermal oxide film (Ox) and the electric power applied to the lower electrode;

FIG. 16 presents a graph illustrating a relation between decrement in the thermal oxide film (Ox) and total flow rate of processing gas; and

FIG. 17 offers a graph showing a relation between decrement in the thermal oxide film (Ox) and O₂ ratio.

### DETAILED DESCRIPTION OF THE PREFERRED EMBODIMENT

Hereinafter, a preferred embodiment of the present invention will be described.

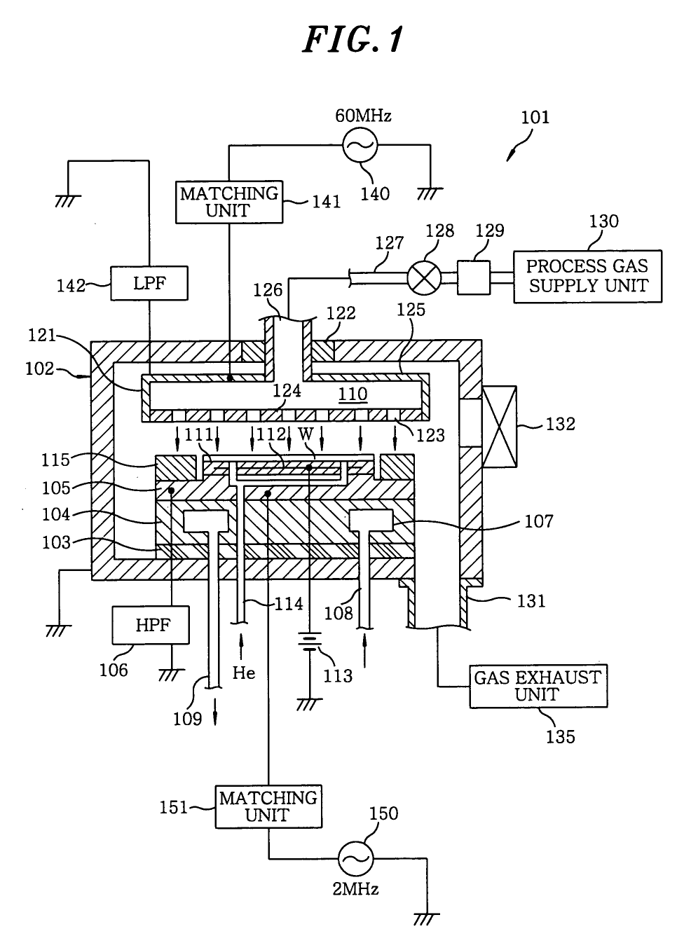

FIG. 1 shows a schematic configuration of a plasma processing apparatus in accordance with a preferred embodiment of the present invention. As shown therein, a plasma processing apparatus 101 includes a plasma processing chamber 102 formed in an approximately cylindrical shape. The plasma processing chamber 102, made of aluminum whose surface is anodic oxidized, is set to be maintained at a ground voltage.

A susceptor supporting table 104 is placed at a bottom portion of the plasma processing chamber 102 via an insulating plate 103 made of, e.g., ceramic material, and a susceptor 105 is mounted on the susceptor supporting table 104. The susceptor 105, serving as a lower electrode as well, is to have a semiconductor wafer W mounted thereon. The susceptor 105 is connected to a high pass filter (HPF) 106.

Inside the susceptor supporting table 104 is installed a temperature control medium container 107. The temperature control medium container 107 is connected to an inlet line 108 and an outlet line 109. Thus, temperature control medium is to be introduced through the inlet line 108 into the temperature control medium container 107 and then circulated inside the temperature control medium container 107 to be exhausted via the outlet line 109, so that it is possible to control the susceptor 105 to be kept at a desired temperature.

The susceptor 105 whose upper central portion is formed as a disk-shaped protrusion has an electrostatic chuck 110 mounted thereon. The electrostatic chuck 110 is structured such that it has an insulating member 111 and inside of the insulating member 111 is inserted an electrode 112 to which a DC power supply 113 is connected. The DC power supply 113 provides the electrode 112 with a DC voltage of, e.g., 1.5 kV, so that a semiconductor wafer W is adsorbed electrostatically onto the electrostatic chuck 110.

Through the insulating plate 103, the susceptor supporting table 104, the susceptor 105 and the electrostatic chuck 110 is formed a gas passage 114 for supplying a heat transfer medium (for example, a He gas) to a back side of the semiconductor wafer W. Heat is transferred between the susceptor 105 and the semiconductor wafer W through the heat transfer medium supplied through the gas passage 114, thereby adjusting temperature of the semiconductor wafer W to be kept at a specified level.

Around a peripheral portion of the susceptor 105 is placed a focus ring 115 of an annular shape in a manner to encircle the semiconductor wafer W mounted on the electrostatic chuck 110. The focus ring 105 is made of ceramic or insulating material such as quartz, or conductive material.

Over the susceptor 105, an upper electrode 121 is installed in a manner to confront the susceptor in parallel. The upper electrode 121 is supported in the plasma processing chamber 102 via an insulating member 122. The upper electrode 121 includes an electrode plate 124 with a plurality of injection holes 123 which confronts the susceptor 105 and an electrode supporting member 125 for supporting the electrode plate 124. The electrode plate 124 is made of insulating or conductive material. In accordance with the present embodiment, the electrode plate 124 is made of silicon. The electrode supporting member 125 is made of conductive material such as aluminum whose surface is anodic oxidized (alumite treated). Further, a gap between the susceptor 105 and the upper electrode 121 can be adjusted.

In the middle of the electrode supporting member 125 is installed a gas inlet 126, which is connected to a gas feeding pipe 127. The gas feeding pipe 127 is connected to a processing gas supply unit 130 via a valve 128 and a mass flow controller 129.

A predetermined processing gas for use in a plasma processing is to be provided from the processing gas supply unit 130. Moreover, although FIG. 1 shows only a single processing gas supply system including the gas feeding pipe 127, the valve 128, the mass flow controller 129 and the processing gas supply unit 130, there is installed a plurality of processing gas supply systems. The processing gas supply systems control flow rates of, e.g., an O2 gas, an Ar gas, a He gas and so forth in an independent manner to provide these gases into the plasma processing chamber 102.

To a bottom portion of the plasma processing chamber 102 is connected a gas exhaust pipe 131, which in turn is connected to a gas exhaust unit 135. The gas exhaust unit 135, including a vacuum pump such as a turbo molecular pump, is capable of exhausting the plasma processing chamber 102 to a given depressurized atmospheric level (for example, 0.67 Pa or below).

At a sidewall of the plasma processing chamber 102 is installed a gate valve 132, which can be opened to let the semiconductor wafer W be loaded into or unloaded from the plasma chamber 102.

The upper electrode 121 is connected to a first high frequency electric power supply 140 by a feed line via a first matching unit 141. Additionally, the upper electrode 121 is connected to a low pass filter (LPF) 142. The first high frequency electric power supply 140 can provide a high frequency electric power for plasma generation, for example, a high frequency electric power in a range between 50 and 150 MHz. In this way, a high-density plasma can be formed in a desirable dissociation state inside the plasma processing chamber 102 through an application of the high frequency electric power to the upper electrode 121, thereby making it possible to perform a plasma processing under a low pressure. A frequency of the first high frequency electric power supply 140 is preferably within a range between 50 and 150 MHz, and typically about 60 MHz as illustrated.

The susceptor 105, serving as a lower electrode, is connected to a second high frequency electric power supply 150 by a feed line via a second matching unit 151. The second high frequency electric power supply 150, generating a self-bias voltage, is capable of providing a high frequency electric power having a frequency lower than the high frequency electric power provided from the first high frequency electric power supply 140, for example, a high frequency electric power having a frequency equal to or higher than several hundred Hz and lower than over ten MHz. By applying an electric power within this frequency range to the susceptor 105, an appropriate ion action can be initiated without inflicting any damage to the semiconductor wafer W. Typically, a frequency of the second high frequency power electric supply 150 is, for example, 2 MHz, 3.2 MHz or 13.56 MHz.

When carrying out a plasma treatment on the semiconductor wafer W by using the plasma processing apparatus of the above-described configuration, firstly the gate valve 132 is opened to let the semiconductor wafer W be loaded into the plasma processing chamber 102 by, e.g., a transfer mechanism which is not illustrated and then mounted on the susceptor 105. Subsequently, the DC power supply 113 applies a DC voltage of, e.g., about 1.5 kV to the electrode 112 in the electrostatic chuck 110, thereby making the semiconductor wafer W electrostatically adsorbed onto the electrostatic chuck 110.

Thereafter, the transfer mechanism is made to recede from the plasma processing chamber 102, the gate valve 132 is closed and then the gas exhaust unit 135 carries out an exhaust process to exhaust the inside of the plasma processing chamber 102 to keep it at a given vacuum level (for example, 4 Pa or below). Moreover, the processing gas supply unit 130 introduces a processing gas (for example, an O₂ gas, an O₂/Ar gaseous mixture, an O₂/He gaseous mixture) into the plasma processing chamber 102 at a given flow rate via the mass flow controller 129 and so forth. In addition, the first high frequency electric power supply 140 applies a high frequency electric power for plasma generation (for example, a high frequency electric power of 60 MHz) to the upper electrode 121 at a given electric power level (for example, 500 W or below (0.81 W/cm² or below)), thereby generating a plasma from the processing gas. Furthermore, the second high frequency electric power supply 150 applies a high frequency electric power for generating a self-bias voltage (for example, a high frequency electric power of 2 MHz) to the susceptor 105 serving as a lower electrode at a given electric power level (for example, 150-350 W (0.28-0.66 W/cm²)), so that ions in the plasma are attracted onto the semiconductor wafer W to be activated, thereby an ashing treatment can be carried out.

Further, after the ashing treatment is completed, the high frequency electric powers and the processing gas cease to be provided and the semiconductor wafer W is unloaded from the plasma processing chamber 102 in a reversed order to that described above. Besides, by changing a processing gas, the plasma processing apparatus 101 can be made to perform an etching treatment and also consecutively perform an etching treatment and an ashing treatment. In this case, it is preferable to carry out a so-called two-step ashing including the first step of carrying out a cleaning process in the plasma processing chamber 102 without an application of a bias voltage from the second high frequency electric power supply 150; and the second step of carrying out an ashing process with an application of a bias voltage from the second high frequency electric power supply 150.

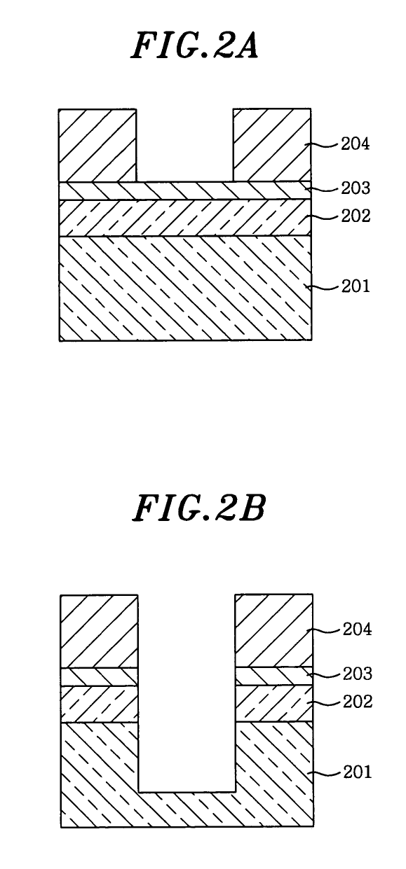

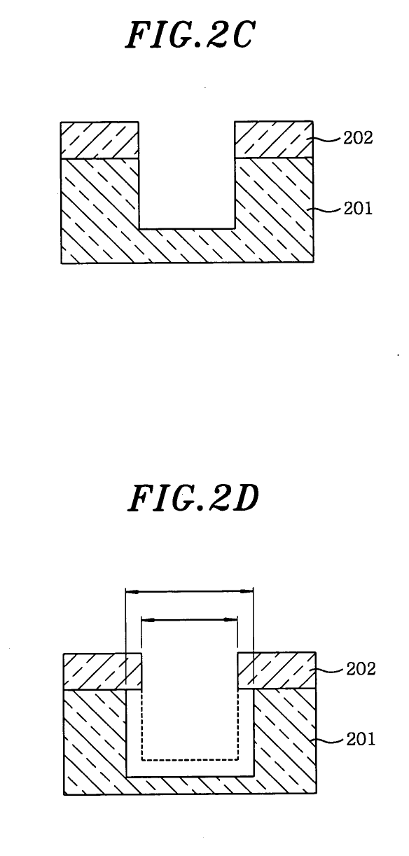

Hereinafter, there will be explained a quantitatively evaluating method for damage inflicted on an organic low-k film by an ashing. FIGS. 2A to 2D schematically represent a cross-sectional configuration of the semiconductor wafer W by enlarging it. As shown in FIG. 2A, there are formed on the semiconductor wafer W an organic low-k film (for example, Porous MSQ (Methyl-hydrogen-SilsesQuioxane)) 201, an SiCN film 202, a bottom anti-reflection coating (BARC) 203 and a resist film 204 in this order from the bottom up. In addition, the resist film is patterned. Further, as the organic low-k film 201 can be used, e.g., Aurora ULK (brand name), which is a SiOCH-based material formed by CVD.

For a start, a state shown in FIG. 2A is changed into a state shown in FIG. 2B by etching the bottom anti-reflection coating (BARC) 203, the SiCN film 202 and the organic low-k film 201 in this order while employing the resist film 204 as a mask.

At this time, an etching of the bottom anti-reflection coating (BARC) 203 is performed with plasma of, e.g., a CF₄ gas.

Further, an etching of the SiCN film 202 is performed with plasma of, e.g., a gaseous mixture of C₄F₈/Ar/N₂.

Still further, an etching of the organic low-k film 201 is performed with plasma of, e.g., a gaseous mixture of CF₄/Ar.

Thereafter, an ashing is carried out with an oxygen plasma under a predetermined condition to remove the resist film 204 and the bottom anti-reflection coating (BARC) 203, so that the state shown in FIG. 2B is changed into a state shown in FIG. 2C. At this time, an exposed surface of the organic low-k film 201 is exposed to the oxygen plasma, thereby getting damaged to be changed into SiO₂.

Here, SiO₂ is soluble in hydrofluoric acid HF whereas the organic low-k film is hardly soluble therein. As a result, if the semiconductor wafer W is treated with hydrof luoric acid, as shown in FIG. 2D, only such parts of the organic low-k film 201 changed into SiO₂ due to damage are removed. In FIG. 2D, dotted lines depict a state before the hydrofluoric acid treatment.

Therefore, if we measure a difference between a width of a groove before the hydrofluoric acid treatment and that after the hydrofluoric acid treatment or a difference between depths of the grooves, the damage inflicted thereon can be evaluated quantitatively in terms of a width of a damaged layer.

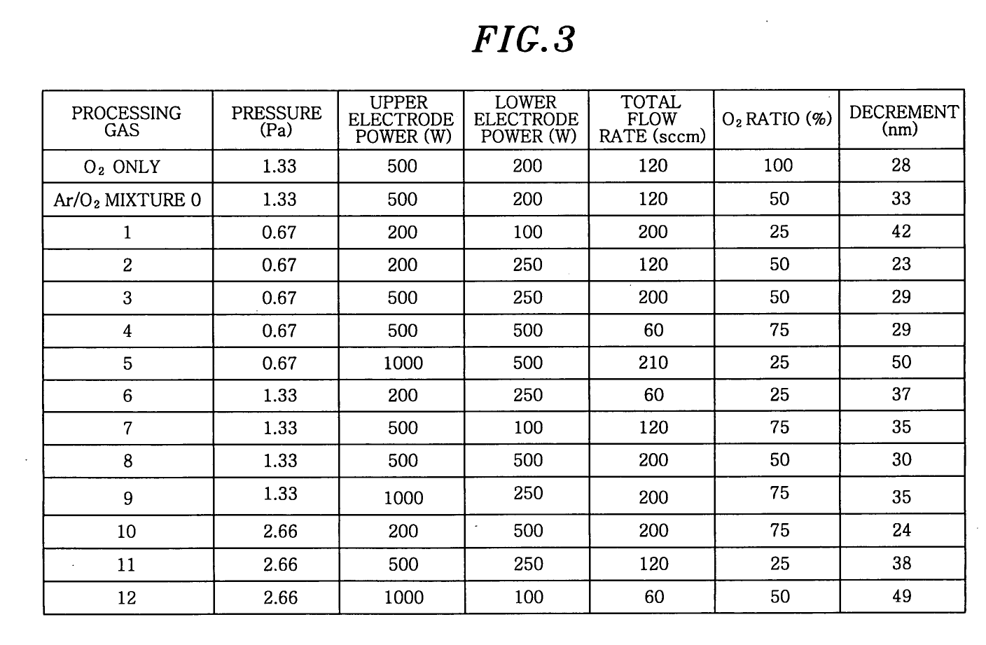

After an ashing process was performed with the plasma processing apparatus shown in FIG. 1 by changing an internal pressure of the plasma processing chamber to 0.67 Pa (5 mTorr), 1.33 Pa (10 mTorr) and 2.66 Pa (20 mTorr); an electric power applied to the upper elctrode 121 (an upper power) to 200 W, 500 W and 1000 W; an electric power applied to the susceptor 105 serving as the lower elctrode (an lower power) to 100 W, 250 W and 500 W; a total flow rate of the processing gas to 60 sccm, 120 sccm and 200 sccm; and an O₂ flow rate ratio with respect to the total flow rate of the processing gas to 25%, 50% and 75%, we actually measured a decrement (nm) in an upper portion of the groove in the organic low-k film 201 (a top CD decrement) and obtained a result shown in FIG. 3. An ashing process time was set a 50% over-ashing (i.e., set to further perform an additional ashing process after completing the removal of the resist film 204 and the bottom anti-reflection coating 203 for an extra period of time equal to 50% of the time taken to complete the removal in the preceded ashing) in a central portion of the semiconductor wafer W. In addition, temperatures were set such that upper portion temperature/sidewall temperature/lower portion temperature: 60° C./50° C./40° C.

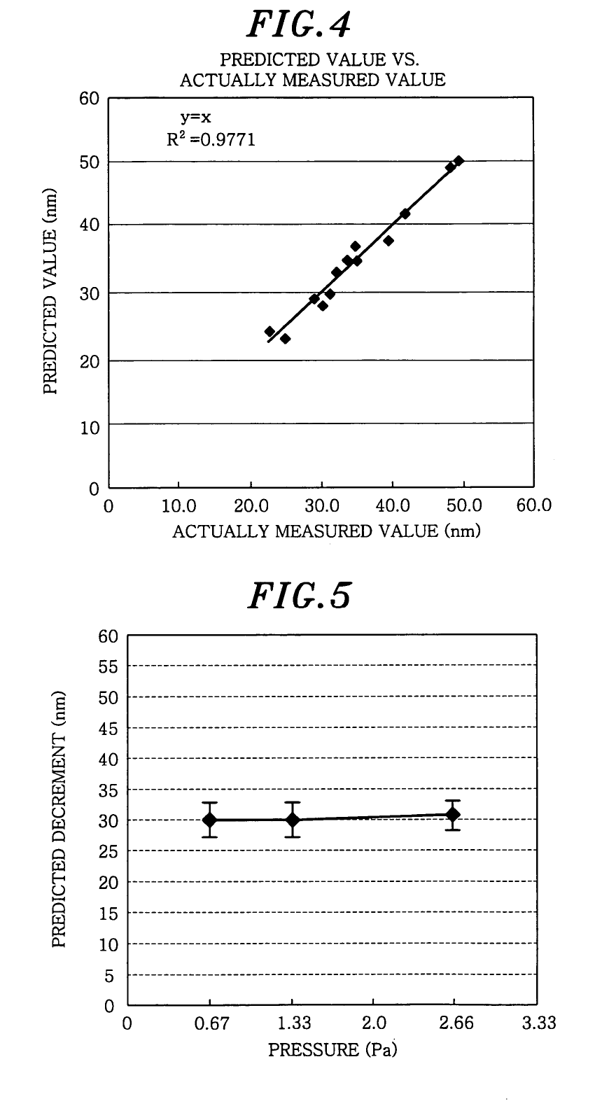

From a multiple regression analysis of the result shown in FIG. 3, we obtained a result as illustrated by a graph of FIG. 4 in which the vertical axis and the horizontal axis represented predicted value and actually measured value, respectively. The multiple correlation coefficient computed from this result was 0.98846 and p-value for the test statistic was 0.0000326. Furthermore, predicted decrements in the organic low-k film 201 obtained from calculations for respective cases of changing the internal pressure, the total flow rate, the upper power, the lower power and the O₂ ratio by using the above result are presented in graphs of FIGS. 5 to 9.

The graph of FIG. 5 shows a relation between the predicted decrement (nm) in the organic low-k film and the pressure (Pa), the former and the latter respectively represented by the vertical axis and the horizontal axis. As shown therein, the pressure does not have a great influence on the decrement in the organic low-k film at a pressure level of 2.66 Pa or below.

The graph of FIG. 6 illustrates a relation between the predicted decrement (nm) in the organic low-k film and the electric power (W) applied to the upper electrode 121, i.e., a first high frequency electric power for generating plasma, the former and the latter respectively represented by the vertical axis and the horizontal axis. For the decrement in the organic low-k film, 35 nm or below is preferable, 30 nm or below is more preferable and 25 nm or below is most preferable. As shown in this graph, the decrement in the organic low-k film becomes smaller as the first high frequency electric power becomes lower. For the first high frequency electric power, 800 W or below is preferable and 500 W or below is more preferable. Since a diameter of the upper electrode 121 is 280 mm, the electric power per square centimeter is 0.81 W/cm².

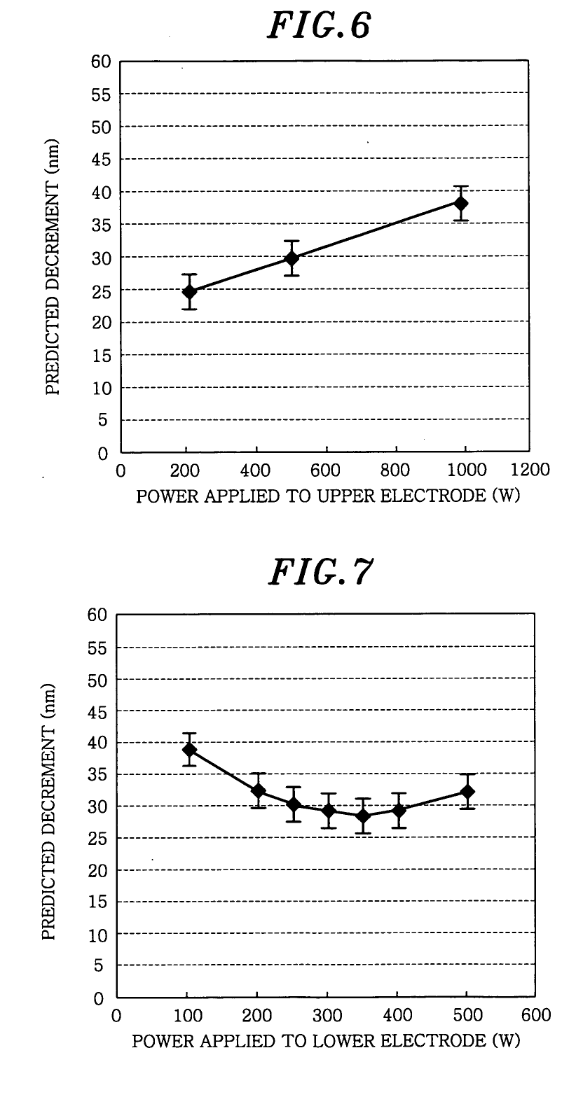

The graph of FIG. 7 shows a relation between the predicted decrement (nm) in the organic low-k film and the electric power (W) applied to the susceptor (lower electrode) 105, i.e., a second high frequency electric power having a frequency lower than the first high frequency electric power, the former and the latter respectively represented by the vertical axis and the horizontal axis. As shown therein, the decrement in the organic low-k film is small in case the second high frequency electric power is moderately high but not too high. It is preferable that the second high frequency electric power range inclusively between 150 and 500 W. In this case, the electric power per square centimeter corresponding thereto ranges inclusively between 0.28 W/cm² and 0.66 W/cm².

The graph of FIG. 8 illustrates a relation between the predicted decrement (nm) in the organic low-k film and the total flow rate (sccm) of the processing gas, the former and the latter respectively represented by the vertical axis and the horizontal axis. As shown therein, the total flow rate of the processing gas does not greatly influence the decrement in the organic low-k film within a range between 60 and 200 sccm.

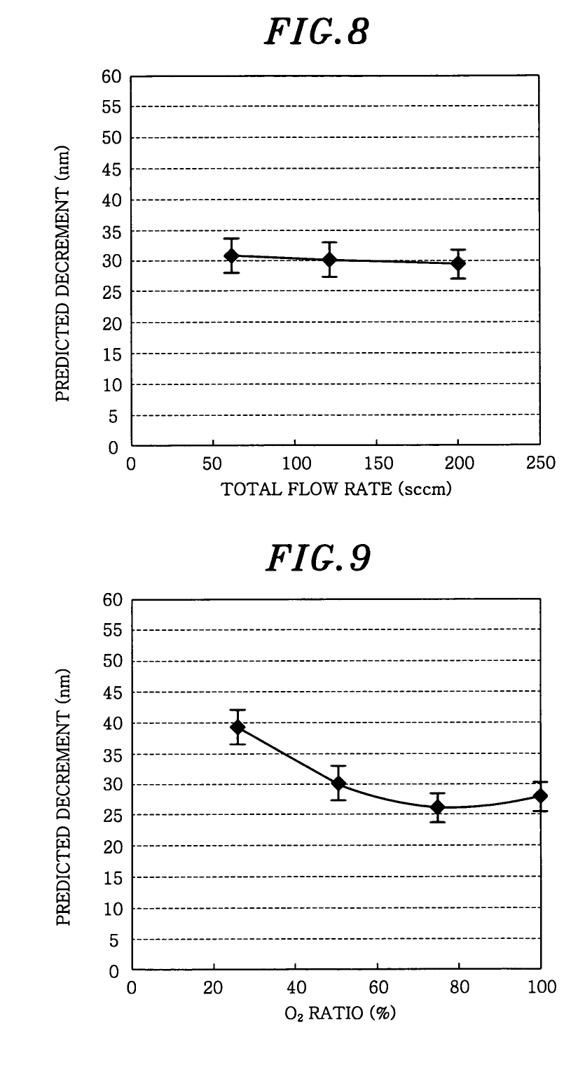

The graph of FIG. 9 shows a relation between the predicted decrement (nm) in the organic low-k film and the O₂ flow rate ratio (W) with respect to the total flow rate of the processing gas, the former and the latter respectively represented by the vertical axis and the horizontal axis. As shown therein, the decrement in the organic low-k film is small for relatively high O₂ ratio. It is preferable that the O₂ ratio be 40% or higher.

The graph of FIG. 10 presents predicted values and actually measured values of the top CD decrement obtained from an experiment performed to verify the predicted results described above, wherein the vertical axis represents the decrement (nm) in the organic low-k film of the upper portion of the groove (top CD decrement) and the horizontal axis represents an Ar flow rate ratio with respect to the total flow rate of the processing gas. The ashing condition of the experiment was as follows: the pressure was 1.33 Pa (10 mTorr); the electric power applied to the upper electrode 121 (the upper power) was 200 W; the electric power applied to the susceptor 105 serving as the lower electrode (the lower power) was 250 W; the total flow rate of the processing gas was 200 sccm; the distance between the two electrodes was 55 mm; the upper portion temperature, the sidewall temperature and the lower portion temperature were 60° C., 50° C. and 40° C., respectively; and, regarding the processing time, a 50% over-ashing was performed- in the central portion of the semiconductor wafer W.

As shown therein, the predicted values are well consistent with the actually measured values. Under the above-mentioned condition, it was possible to keep the top CD decrement below approximately 25 nm when the Ar ratio was 60% or below, i.e., the O₂ ratio was 40% or above.

Furthermore, whereas the internal pressure of the plasma chamber 102 was kept within a range between 0.67 Pa (5 mTorr) and 2.66 Pa (20 mTorr) in the above-described case of appraising the ashing condition, we actually measured the decrement in the organic low-k film in case where the pressure exceeded this range. The O₂ ratio was set to 75% and 100%. Besides the pressure and the O₂ ratio, the other factors of the ashing condition were set to be same as those in the above-described case. In this case, we could keep the decrement in the organic low-k film, e.g., the top CD decrement bellow 25 nm (about 21 to 24 nm) while the pressure was kept below 4.0 Pa (30 mTorr). However, when the pressure was raised to, e.g., 6.7 Pa (50 mTorr), the top CD decrement increased to about 50 nm. Therefore, it is preferable that the internal pressure of the plasma processing chamber 102 be kept at 4.0 Pa (30 mTorr) or below.

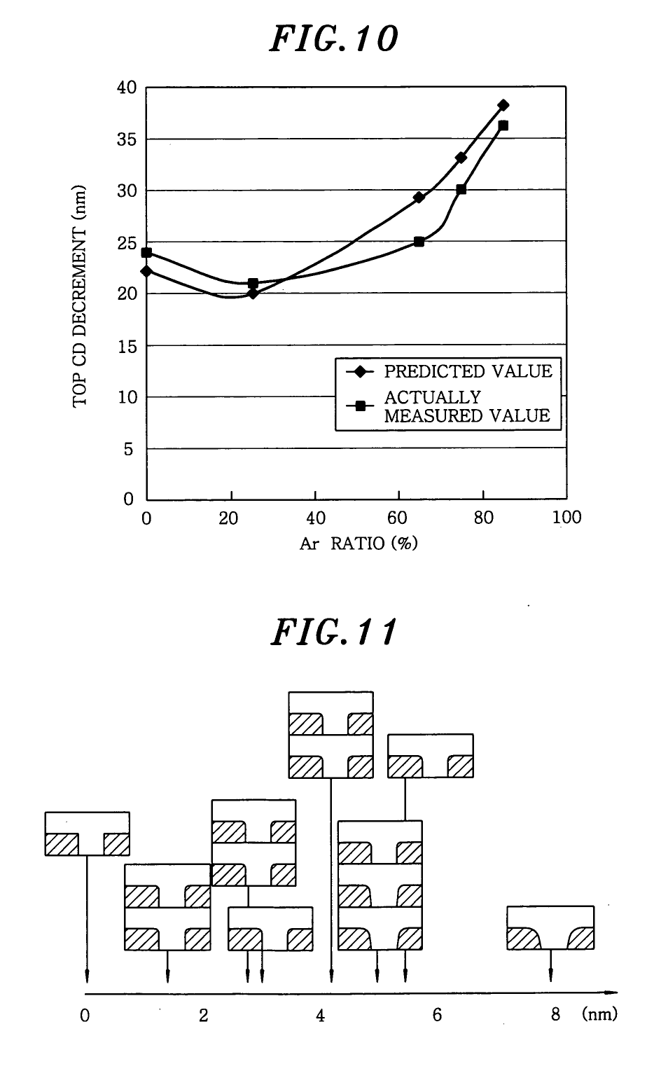

In the following, there will be described a result of an inspection concerning a facet due to the ashing, in other words, an edge of the upper portion in the groove shown in FIGS. 2C and 2D being sloped instead of being vertical. A facet comes about when some parts that are not usually worn away through an oxygen plasma ashing are worn away due to a sputtering. We inspected a correlation between a decrement in a thermal oxide film (Ox) formed on a wafer due to a sputtering and a facet and found that, as shown in FIG. 11, an increase in the decrement in the thermal oxide film (Ox) was clearly correlated with an increase in the facet. In FIG. 11, the horizontal axis represents the decrement (nm) in the thermal oxide film (Ox) and the above thereof are provided schematic views depicting the facet due to the ashing observed with an electron microscope. As shown therein, the facet increases as the decrement in the thermal oxide film (Ox) increases. We measured the decrement in the thermal oxide film due to the ashing under the same ashing condition as the case shown in FIG. 3.

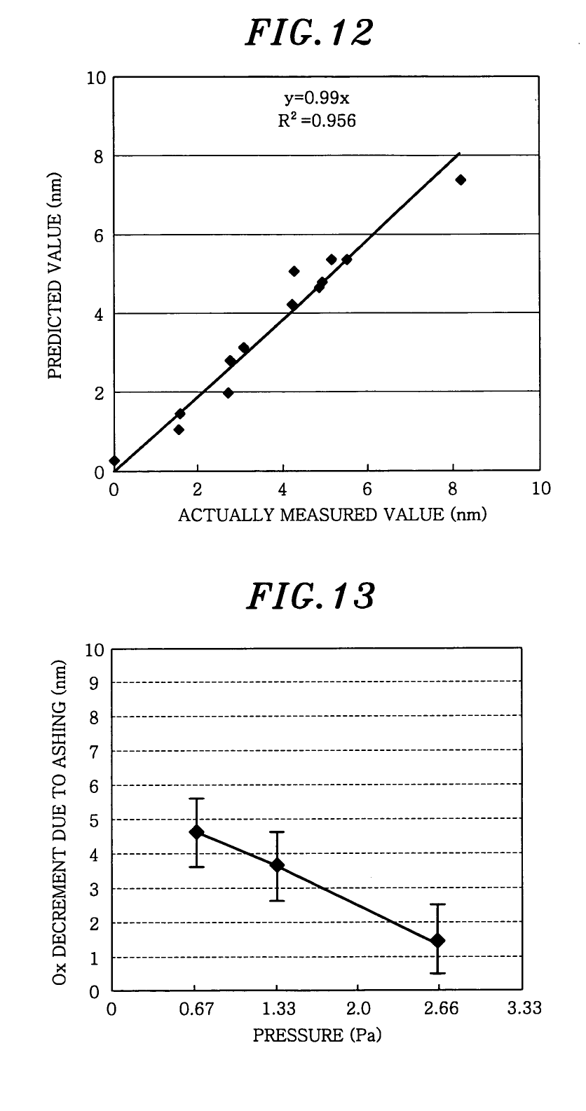

A result of a multiple regression analysis of the result of this measurement of the decrement in the thermal oxide film (Ox) due to the ashing is presented in a graph of FIG. 12 in which the vertical axis and the horizontal axis represent predicted value and actually measured value, respectively. The multiple correlation coefficient computed from this result was 0.978 and p-value for the test statistic was 0.000118. Further, decrements in the thermal oxide film (Ox) due to the ashing obtained from calculations for respective cases of changing the internal pressure, the total flow rate, the upper power, the lower power and the O₂ ratio by using the above result are presented in graphs of FIGS. 13 to 17.

The graph of FIG. 13 shows a relation between the predicted decrement (nm) in the thermal oxide film (Ox) and the pressure (Pa), the former and the latter respectively represented by the vertical axis and the horizontal axis. As shown therein, the decrement (nm) in the thermal oxide film (Ox) increases as the pressure is lowered. Therefore, in view of the facet, it is required that the pressure be kept at 1.33 Pa (10 mTorr) or higher. Therefore, considering the above-described preferable pressure range, it is preferable that the pressure be kept within a range between 1.33 (10 mTorr) and 4.0 Pa (30 mTorr) during the ashing.

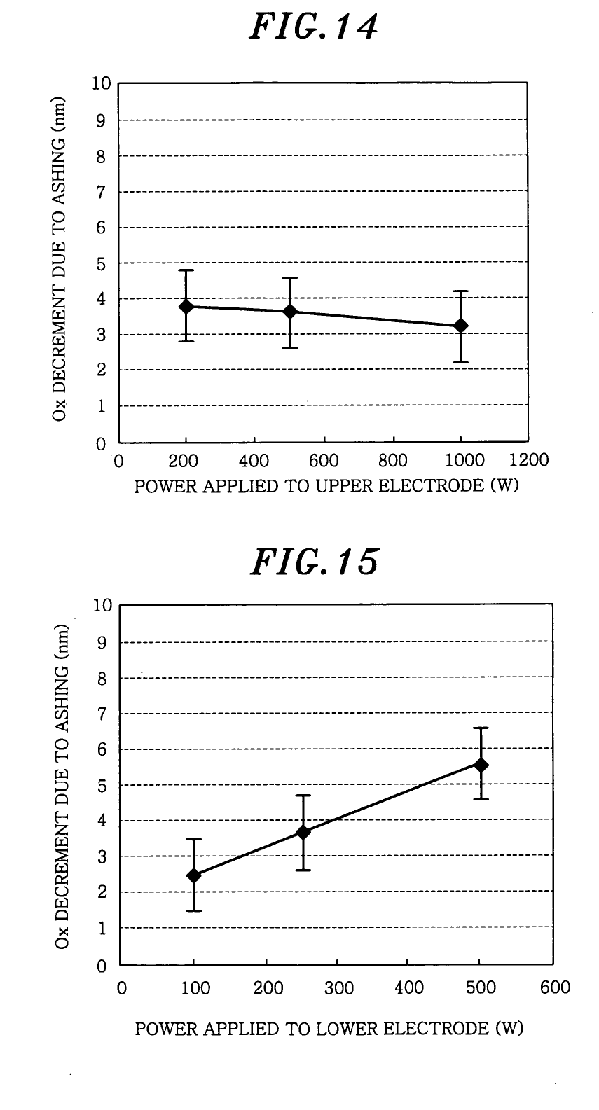

The graph of FIG. 14 illustrates a relation between the predicted decrement (nm) in the thermal oxide film (Ox) due to the ashing and the electric power (W) applied to the upper electrode 121, i.e., a first high frequency electric power for generating plasma, the former and the latter respectively represented by the vertical axis and the horizontal axis. As shown therein, the first high frequency electric power does not greatly influence the decrement in the thermal oxide film (Ox), i.e., the amount of the facet.

The graph of FIG. 15 shows a relation between the predicted decrement (nm) in the thermal oxide film (Ox) and the electric power (W) applied to the susceptor (lower electrode) 105, i.e., the second high frequency electric power having a frequency lower than the first high frequency electric power, the former and the latter respectively represented by the vertical axis and the horizontal axis. As shown therein, the decrement of the thermal oxide film (Ox), i.e., the amount of the facet increases as the second high frequency electric power goes up. Therefore, considering the above-mentioned electric power range (see FIG. 7) as well, it is preferable that the second high frequency electric power range inclusively between 150 and 350 W (0.28 W/cm²−0.66 W/cM²).

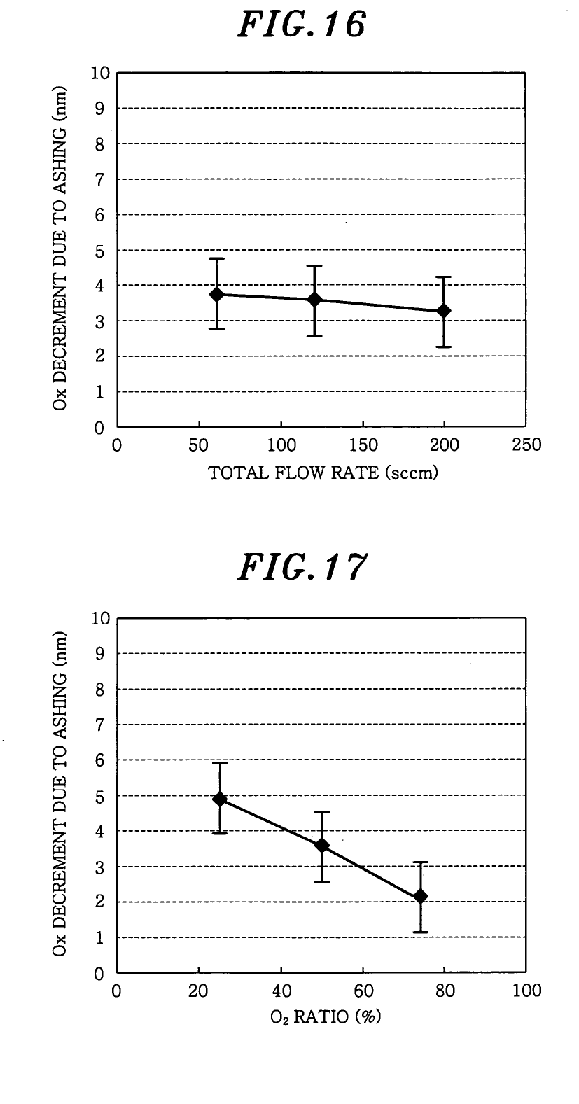

The graph of FIG. 16 illustrates a relation between the predicted decrement (nm) in the thermal oxide film (Ox) and the total flow rate (sccm) of the processing gas, the former and the latter respectively represented by the vertical axis and the horizontal axis. As shown therein, the total flow rate of the processing gas does not greatly influence the decrement in the thermal oxide film (Ox), i.e., the amount of the facet, within a range between 60 and 200 sccm.

The graph of FIG. 17 shows a relation between the predicted decrement (nm) in the thermal oxide film (Ox) and the O₂ flow rate ratio (W) with respect to the total flow rate of the processing gas, the former and the latter respectively represented by the vertical axis and the horizontal axis. As shown therein, the decrement in the thermal oxide film (Ox), i.e., the amount of the facet, decreases as the O₂ ratio increases. Therefore, in view of the amount of the facet, it is preferable that the O₂ ratio be 50% or higher and it is preferable to use, for example, an O₂ gas which does not include Ar by setting the O₂ ratio to 100%. However, it is difficult to generate an electric discharge in case when O₂ gas is only used at a low pressure. Therefore, to sustain the electric discharge, it is preferable to add Ar to the O₂ gas. In addition, it is difficult to ignite the plasma in case the pressure is lower than 4.0 Pa (30 mTorr). In conclusion, it is preferable to set the pressure to 4.0 Pa (30 mTorr) at an ignition stage which lasts for, e.g., 3 seconds and then set the pressure to a predetermined pressure below 4.0 Pa (30 mTorr) at the remaining ashing stage, or to raise the voltage applied to the upper electrode temporarily at the ignition stage.

Furthermore, by performing the operation by adding a He gas instead of the Ar gas, we obtained a similar result to the above-described case of adding the Ar gas. However, in case of adding the He gas, it is preferable to set the O₂ ratio approximately to 25% or higher because a low O₂ ratio seldom causes adverse effects. This is because He is light and thus easy to be exhausted. Therefore, when a large amount of additional gas needs to be added in order to improve, e.g., the uniformity of the ashing process, it is more preferable to add a He gas rather than an Ar gas.

Besides, although the above-described embodiment was the case where the first high frequency electric power having a higher frequency is applied to the upper electrode 121 and the second high frequency electric power having a lower frequency is applied to the susceptor (the lower electrode) 105, the present invention should not be construed to be limited thereto. It is also possible, for example, to apply both the first high frequency electric power having a higher frequency and the second high frequency electric power having a lower frequency to the lower electrode.

Still further, the present invention can also be applied to the case of a so-called two-step ashing where, at the first step, a cleaning is performed in the plasma processing chamber without applying a bias voltage and, at the second step, an ashing is performed on the substrate to be ashed by applying the bias voltage. In this case, the present invention can be applied at the second step.

While the invention has been shown and described with respect to the preferred embodiments, it will be understood by those skilled in the art that various changes and modifications may be made without departing from the spirit and scope of the invention as defined in the following claims.

1. A plasma processing method using a processing gas including at least oxygen to ash a substrate to be ashed having an organic low-k film and a resist film formed thereon to thereby remove the resist film, wherein a pressure in a plasma processing chamber is 4 Pa or lower, the plasma processing method comprising:
the step of applying a first high frequency electric power having a first frequency to generate plasma of the processing gas; and
the step of applying a second high frequency electric power having a second frequency lower than the first frequency to an electrode mounted thereon the substrate to be ashed to thereby generate a self-bias voltage,
wherein an applied voltage of the first high frequency electric power is 0.81 W/cm² or less.

2. The plasma processing method of claim 1, wherein the organic low-k film includes Si, O, C and H.

3. The plasma processing method of claim 1, wherein an upper electrode is placed in the plasma processing chamber to confront the electrode having the substrate to be ashed mounted thereon and the first high frequency electric power is applied to the upper electrode.

4. The plasma processing method of claim 1, wherein the pressure in the plasma processing chamber is 1.3 Pa or higher.

5. The plasma processing method of claim 1, wherein an applied power of the second high frequency electric power ranges inclusively between 0.28 W/cm² and 0.66 W/cm².

6. The plasma processing method of claim 1, wherein the processing gas is an O₂ gas.

7. The plasma processing method of claim 1, wherein the processing gas is a gaseous mixture of O₂/Ar, and a ratio of an O₂ flow rate with respect to an O₂/Ar flow rate is 40% or higher.

8. The plasma processing method of claim 1, wherein the processing gas is a gaseous mixture of O₂/He, and a ratio of an O₂ flow rate with respect to an O₂/He flow rate is 25% or higher.

9. A plasma processing apparatus for ashing a substrate to be ashed having an organic low-k film and a resist film formed thereon to remove the resist film, comprising:
a plasma processing chamber in which a pressure is 4 Pa or lower;
a processing gas supply unit for supplying a processing gas including at least oxygen into the plasma processing chamber;
an electrode placed in the plasma processing chamber and having the substrate to be ashed mounted thereon;
a first high frequency electric power supply unit for applying a high frequency electric power having a first frequency and a magnitude of 0.81 W/cm² or less; and
a second high frequency electric power supply unit for applying a high frequency electric power having a second frequency to generate a self-bias voltage.

10. The plasma processing apparatus of claim 9, wherein an upper electrode is placed in the plasma processing chamber to confront the electrode having the substrate to be ashed mounted thereon and the first high frequency electric power supply unit supplies the high frequency electric power.

11. The plasma processing apparatus of claim 9, wherein the pressure in the plasma processing chamber is 1.3 Pa or higher.

12. The plasma processing apparatus of claim 9, wherein the second high frequency electric power supply unit supplies an electric power ranging between 0.28 W/cm² and 0.66 W/cm².

13. The plasma processing apparatus of claim 9, wherein the processing gas supply unit supplies an O₂ gas.

14. The plasma processing method of claim 9, wherein the processing gas supply unit supplies a gaseous mixture of O₂/Ar, and a ratio of an O₂ flow rate with respect to an O₂/Ar flow rate is 40% or higher.

15. The plasma processing method of claim 9, wherein the processing gas supply unit supplies a gaseous mixture of O₂/He, and a ratio of an O₂ flow rate with respect to an O₂/He flow rate is 25% or higher.
